(19) United States
(12) Patent Application Publication
(10) Pub. No.: US 2007/0084828 A1
(43) Pub. Date: Apr. 19, 2007

(54) Polishing composition for a semiconductor substrate

(75) Inventors: Yasuhiro Yoneda, Wakayama-shi (JP); Mami Shirota, Wakayama-shi (JP); Haruki Nojo, Kanagawa-ken (JP); Hirofumi Kashihara, Kyotanabe-shi (JP)

Correspondence Address: BIRCH STEWART KOLASCH & BIRCH, PO BOX 747, FALLS CHURCH, VA, 22040-0747, US

(73) Assignee: Kao Corporation

(21) Appl. No.: 11/546,427

(22) Filed: Oct. 12, 2006

(30) Foreign Application Priority Data
Oct. 14, 2005 (JP) 2005-300633

(51) Int. Cl. C09K 13/00; H01L 21/461; C03C 15/00; B44C 1/22; H01L 21/302

(52) U.S. Cl. 216/88; 438/692; 252/79.1

(57) ABSTRACT

A polishing composition for a semiconductor substrate comprising dihydroxyethylglycine, ceria particles, a dispersant, and an aqueous medium, wherein the ceria particles are contained in an amount of from 2 to 22% by weight of the polishing composition, and the dispersant is contained in an amount of from 0.001 to 1.0% by weight of the polishing composition; a polishing process of a semiconductor substrate with the polishing composition for a semiconductor substrate; and a method for manufacturing a semiconductor device including the step of polishing a substrate to be polished in accordance with the polishing process. The polishing composition is used, for example, for the steps of subjecting to shallow trench isolation, subjecting an interlayer dielectric to planarization, forming an embedded metal line, forming an embedded capacitor, and the like. Especially, the method is suitable for the step of shallow trench isolation or the step of subjecting an interlayer dielectric to planarization, and preferably used for manufacturing a semiconductor device such as memory ICs, logic ICs, or system LSIs.

### FIELD OF THE INVENTION

The present invention relates to a polishing composition for a semiconductor substrate, a polishing process of a semiconductor substrate with the polishing composition for a semiconductor substrate, and a method for manufacturing a semiconductor device including the step of polishing a substrate to be polished in accordance with the polishing process.

### BACKGROUND OF THE INVENTION

It is desired that the polishing composition for a semiconductor substrate is manufactured as a highly concentrated article and diluted upon use to a given concentration from the viewpoint of reducing manufacturing equipments and transportation costs. However, the higher the concentration, the more likely the components to be aggregated and precipitated, so that a polishing composition having even more excellent dispersion stability is in demand.

Especially, the ceria (cerium oxide) particles that are widely used as abrasive in a polishing composition have a specific gravity as large as about 7.3 g/cm³, the ceria particles are liable to be precipitated. Further, the additive which serves to impart planarization property promotes the aggregation of the ceria particles, thereby accelerating the precipitation, so that the dispersion stability is likely to be lowered. As a result, the precipitation in the feed pipe of the polishing composition or clogging of the filter is generated which causes increase in scratches.

As a technique of making it less likely to precipitate the ceria particles, a polishing composition in which a polyacrylic acid-based copolymer is selected as an additive has been known (JP2000-17195 A). However, in this polishing composition, since the amount of the copolymer is slight, polishing not only in projection portions but also in dent portions are progressed when a surface to be polished having a step height is polished, so that dishing is generated, whereby a planar semiconductor substrate cannot be obtained.

On the other hand, in the field of semiconductors in recent years, higher integration and speeding up have become advanced, and the production of thinner wiring has been required especially in high integration. As a result, in the manufacturing process for a semiconductor substrate, since the focal depth becomes shallower during the exposure of a photoresist, even more improvement in surface planarization is desired. In addition, with the advancement of higher integration and thinner wiring, the disconnection of the circuit or the like due to the presence of defects on a polished wafer surface is generated, and an yield of the excellent chips is lowered, so that the reduction in defects is even more in demand.

In the manufacturing process for a semiconductor substrate, for example, in the step of forming wiring or the step of shallow trench isolation, there are numerous fine projections and dents having various widths due to formation of channels for wiring or embedding on the substrate. Therefore, planarization of the step height between the projections and dents and reduction of defects are in demand.

When the step height between the dents and projections on the surface of this substrate are polished, there are some disadvantages that the projection portions are rapidly polished with a polishing composition containing only an abrasive, and the dent portions are also polished at the same time, so that it is time-consuming, and it is also necessary to polish a considerable amount of a member of a surface to be polished, to achieve substantial planarization of both the dent and projection portions.

In view of the above, in a conventional technique, improvement of planarization property by adding a low-molecular additive such as aspartic acid has been tried (see, for example, JP 2001-7059 A).

### SUMMARY OF THE INVENTION

The present invention relates to:
[1] a polishing composition for a semiconductor substrate containing dihydroxyethylglycine, ceria particles, a dispersant, and an aqueous medium, wherein the ceria particles are contained in an amount of from 2 to 22% by weight of the polishing composition, and the dispersant is contained in an amount of from 0.001 to 1.0% by weight of the polishing composition;
[2] a polishing composition for a semiconductor substrate obtainable by a process comprising mixing dihydroxyethylglycine, ceria particles, a dispersant, and an aqueous medium, wherein an amount of the ceria particles is from 2 to 22% by weight, and an amount of the dispersant is from 0.001 to 1.0% by weight, of the polishing composition;
[3] a polishing process of a semiconductor substrate, including the step of feeding a liquid mixture prepared by diluting the polishing composition as defined in the above [1] or [2] to a substrate to be polished at a rate of from 0.01 to 10 g/min per 1 cm² of the substrate; and
[4] a method for manufacturing a semiconductor device, including the step of polishing a substrate to be polished with the polishing process as defined in the above [3].

### DETAILED DESCRIPTION OF THE INVENTION

In the polishing composition described in JP 2001-7059 A, dispersion stability of the above-mentioned ceria particles is not sufficient, so that effective improving strategy has not been presented. The present invention relates to a polishing composition for a semiconductor substrate, which has excellent dispersion stability of ceria particles, and is capable of preparing a highly concentrated produced with stable quality, so that when used in dilution, imparts selective polishing property in the projection portion and is less likely to be influenced by density or size of dent and projection patterns, in other words, a high level of planarization having little pattern dependence can be quickly achieved in a smaller polished amount, and is capable of reducing defects after polishing; a polishing process of a semiconductor substrate with the polishing composition for a semiconductor substrate; and a method for manufacturing a semiconductor device, including the step of polishing a substrate to be polished in accordance with the polishing process.

According to the present invention, there can be provided a polishing composition for a semiconductor substrate, which has excellent dispersion stability of ceria particles, and is capable of preparing a highly concentrated produced with stable quality, so that when used in dilution, imparts selective polishing property in the projection portion and is less likely to be influenced by density or size of dent and projection patterns, in other words, a high level of planarization having little pattern dependence can be quickly achieved in a smaller polished amount, and is capable of reducing defects after polishing; a polishing process of a semiconductor substrate with the polishing composition for a semiconductor substrate; and a method for manufacturing a semiconductor device, including the step of polishing a substrate to be polished in accordance with the polishing process.

These and other advantages of the present invention will be apparent from the following description.

The polishing composition for a semiconductor substrate of the present invention (hereinafter simply referred to as “polishing composition”), as mentioned above, dihydroxyethylglycine, ceria particles, a dispersant and an aqueous medium, wherein the ceria particles are contained in an amount of from 2 to 22% by weight of the polishing composition, and the dispersant is contained in an amount of from 0.001 to 1.0% by weight of the polishing composition. Since the present invention has the above constitution, there are exhibited some effects that the polishing composition has excellent dispersion stability of ceria particles, and is capable of preparing a highly concentrated produced with stable quality, so that when used in dilution, imparts selective polishing property in the projection portion and is less likely to be influenced by density or size of dent and projection patterns, in other words, a high level of planarization having little pattern dependence can be quickly achieved in a smaller polished amount.

[Mechanism]

The reason why the polishing composition of the present invention shows a high level of planarization property and has excellent dispersion stability in ceria particles is presumably due to the fact that the following mechanisms take place by the co-presence of the ceria particles and dihydroxyethylglycine.

Since dihydroxyethylglycine contains an anionic group, a cationic group, and a nonionic group within its molecule in a good balance, it is presumed that zeta potential of the particles and the hydrophilicity are not significantly lowered even when the dihydroxyethylglycine is adhered to ceria particles, and that the dihydroxyethylglycine is less likely to influence the dispersant. Further, since the dihydroxyethylglycine does not have a cross-linking effect between the ceria particles as in the polymer compound, it is presumed that the ceria particles have excellent dispersion stability even in a case where the dihydroxyethylglycine is added in a high concentration.

On the other hand, when the polishing composition is fed to a semiconductor substrate, dihydroxyethylglycine is adsorbed to a surface of ceria particles and/or a surface of a film to be polished to form a coating film. The coating film formed on the surface inhibits the action of the ceria particles on the surface of the film to be polished, thereby suppressing the polishing rate. When a high polishing load is applied to the surface, the adsorption coating film of dihydroxyethylglycine is broken, so that the ceria particles can act on the surface of the film to be polished, and thereby polishing is progressed. Therefore, when a film to be polished having different step height of dents and projections is polished, a high polishing load is locally applied to the projection portions, so that the adsorption coating film is broken, and whereby the polishing progresses. By contrast, since a low load is locally applied to the dent portions, the surface is protected by the adsorption coating film, and whereby the polishing does not progress. Therefore, the polishing is selectively performed only on the projection portions, thereby efficiently progressing the reduction in the step height.

Furthermore, when polishing is progressed to reduce the step height, local loads applied to the projection portions and the dent portions approximate the set load. Therefore, by setting the polishing load in advance so that polishing is less likely to progress on the plane portion, characteristic polishing properties (polishing rate selectivity for projection portion/plane portion) that the polishing is less likely to progress after the disappearance of the step height (after planarization) can be exhibited.

As a result, an excellent effect that a high level of planarization with lower pattern dependency can be accomplished with a smaller polished amount is exhibited. This effect is also remarkable in a case where a film of the surface of a semiconductor substrate contains at least a silicon atom, and even more preferably in a case where a film contains silicon oxide.

(1) Polishing Composition

[Ceria Particles]

The ceria particles used for the present invention include those which are prepared by various preparation processes. The preparation processes include calcination method, hydrothermal synthesis method, salt catalysis method, vapor phase method (PSV method) and the like. Among them, the calcination method including the step of calcining a cerium compound of a carbonate, a sulfate, an oxalate or the like to give cerium oxide (ceria) is preferable, from the viewpoint of polishing rate.

The ceria particles have a volume-average particle size of preferably 30 nm or more from the viewpoint of the polishing rate, and a volume-average particle size of preferably 1000 nm or less from the viewpoint of dispersion stability and prevention of separation by precipitation of ceria particles in an aqueous medium. The ceria particles have a volume-average particle size of preferably from 30 to 1000 nm, more preferably from 40 to 500 nm, even more preferably from 50 to 160 nm, and even more preferably from 50 to 140 nm. Here, the volume-average particle size can be obtained from, for example, a median size on a volume basis as obtained by determining the particle size in a diluted state while ultrasonically dispersing the ceria particles with laser diffraction/scattering particle size analyzer (commercially available from Horiba LTD. under the trade name of LA-920).

In addition, the ceria particles have an average primary particle size (crystallite size) of preferably 5 nm or more from the viewpoint of polishing rate, and an average primary particle size of preferably 100 nm or less from the viewpoint of suppressing generation of scratches on the polished surface. The above-mentioned ceria particles have an average primary particle size of preferably from 5 to 100 nm, more preferably from 10 to 50 nm, and even more preferably from 20 to 40 nm. Here, a method for determining the average primary particle size of the ceria particles includes a method for determining the particle size from a specific surface area determined according to BET method, supposing that the shape of particles is spherical, or a X-ray diffraction method.

The content of the ceria particles is 2% by weight or more of the polishing composition, from the viewpoint of preparation and transportation costs, and the content is 22% by weight or less of the polishing composition, from the viewpoint of dispersion stability and prevention of separation by precipitation of ceria particles in an aqueous medium. Therefore, the above-mentioned content is from 2 to 22% by weight, preferably from 2 to 15% by weight, more preferably from 2.5 to 12% by weight, even more preferably from 3 to 10% by weight, and even more preferably from 3 to 8% by weight, of the polishing composition.

When the polishing composition is diluted upon use, the content of the ceria particles is preferably 0.1% by weight or more, more preferably 0.2% by weight or more, even more preferably 0.4% by weight or more, and even more preferably 0.5% by weight or more, of the polishing composition, from the viewpoint of polishing rate, and the content is preferably 8% by weight or less, more preferably 5% by weight or less, even more preferably 4% by weight or less, and even more preferably 3% by weight or less, of the polishing composition, from the viewpoint of dispersion stability of the ceria particles in the aqueous medium and cost. Therefore, upon use, the above content is preferably from 0.1 to 8% by weight, more preferably from 0.2 to 5% by weight, even more preferably from 0.4 to 4% by weight, and even more preferably from 0.5 to 3% by weight, of the polishing composition.

[Dihydroxyethylglycine]

The content of the dihydroxyethylglycine is preferably 0.4% by weight or more of the polishing composition, from the viewpoint of preparation and transportation costs, and the content is preferably 40% by weight or less of the polishing composition, from the viewpoint of dispersion stability and prevention of separation by precipitation of ceria particles in an aqueous medium. Therefore, the above-mentioned content is preferably from 0.4 to 40% by weight, more preferably from 1 to 20% by weight, even more preferably from 2 to 15% by weight, and even more preferably from 3 to 12% by weight, of the polishing composition.

When the polishing composition is diluted upon use, the content of the dihydroxyethylglycine is preferably 0.2% by weight or more of the polishing composition, and the content is preferably 10% by weight or less of the polishing composition, from the viewpoint of planarization property. Therefore, the above-mentioned content is preferably from 0.2 to 10% by weight, more preferably from 0.5 to 8% by weight, and even more preferably from 1 to 6% by weight of the polishing composition.

The polishing composition can contain other components within the range that does not impair the effects of the present invention. The content of dihydroxyethylglycine is preferably 80% by weight or more, more preferably 90% by weight or more, even more preferably 95% by weight or more, and even more preferably 97% by weight or more, of the components excluding the aqueous medium and the ceria particles from the polishing composition of the present invention, from the viewpoint of planarization property. Even more, the content of the dihydroxyethylglycine is preferably 99.9999% by weight or less, more preferably 99.999% by weight or less, even more preferably 99.98% by weight or less, and even more preferably 99.97% by weight or less, of the polishing composition. Therefore, the above-mentioned content is preferably from 80 to 99.9999% by weight, more preferably from 90 to 99.999% by weight, even more preferably from 95 to 99.98% by weight, and more preferably from 97 to 99.97% by weight, of the components excluding the aqueous medium and the ceria particles from the polishing composition of the present invention.

[Ratio of Contents of Dihydroxyethylglycine to Ceria Particles (Weight Ratio)]

In the polishing composition of the present invention, the ratio of the contents of the dihydroxyethylglycine to the ceria particles (weight ratio) is preferably 1/5 or more, more preferably 1/4 or more, and even more preferably 1/3 or more, from the viewpoint of prevention of dishing and reduction of defects, and the ratio of the contents is preferably 15/1 or less, more preferably 12/1 or less, and even more preferably 10/1 or less, from the viewpoint of rate of planarization.

Therefore, the ratio of the contents of the dihydroxyethylglycine to the ceria particles (weight ratio) is preferably from 1/5 to 15/1, more preferably from 1/4 to 12/1, and even more preferably from 1/3 to 10/1.

[Dispersant]

The dispersant includes surfactants such as anionic surfactants and nonionic surfactants; polymeric dispersants such as acrylic acid copolymers, ethylene oxide-propylene oxide block copolymers (Pluronics); and the like. Among them, the acrylic acid copolymers are preferable, and a polyacrylic acid or a salt thereof is even more preferable, from the viewpoint of dispersion effect, and the polyacrylic acid copolymer has a weight-average molecular weight of preferably from 1,000 to 10,000, and more preferably from 1,000 to 6,000. Here, the weight-average molecular weight mentioned above is a value determined by gel permeation chromatography (GPC) method as detailed hereinbelow.

<GPC Conditions>

| | |
|---|---|
| Column: | G4000PWXL + G2500PWXL (commercially |
| | available from Tosoh Corporation) |
| Eluent: | 0.2 M Phosphate buffer/CH₃CN = 9/1 |
| Flow rate: | 1.0 mL/min |
| Column temperature: | 40° C. |
| Detection: | RI |
| Standard substance: | calculated as polyacrylic acid |

In addition, the content of the dispersant is from 0.001 to 1.0% by weight, preferably from 0.003 to 0.3% by weight, and more preferably from 0.005 to 0.1% by weight, of the polishing composition, from the viewpoint of obtaining an appropriate dispersion effect.

When the polishing composition is diluted upon use, the content of the dispersant is preferably from 0.0005 to 0.5% by weight, and more preferably from 0.001 to 0.1% by weight, of the polishing composition, from the viewpoint of dispersion effect.

Here, the preferred salts of the acrylic acid copolymer include ammonium salts, tetramethylammonium salts, water-soluble amine salts, potassium salts, and the ammonium salts are more preferable, from the viewpoint of dispersion effect.

[Aqueous Medium]

In the present invention, an aqueous medium refers to water or a mixed medium of water and a water-miscible aqueous medium such as an alcohol. The aqueous medium is preferably water such as an ion-exchanged water.

The content of the aqueous medium is preferably from 60 to 97.599% by weight, and more preferably from 70 to 96% by weight of the polishing composition, from the viewpoint of increasing the polishing rate and the viewpoint of dispersion stability and prevention of precipitation and separation of the ceria particles in an aqueous medium.

When the polishing composition is diluted upon use, the content of the aqueous medium is preferably from 80 to 99.6995% by weight, and more preferably from 85 to 99% by weight of the polishing composition, from the viewpoint of increasing the polishing rate and the viewpoint of dispersion stability and prevention of precipitation and separation of the ceria particles in an aqueous medium.

[Process for Preparing a Polishing Composition]

The polishing composition of the present invention can be prepared by combining the ceria particles, the dihydroxyethylglycine, the dispersant and optional components mentioned below as desired with the aqueous medium mentioned above. Especially, a process including the steps of preparing in advance an aqueous dispersion containing ceria particles, or containing ceria particles and a dispersant (ceria slurry), and mixing the resulting ceria slurry and an aqueous solution prepared by dissolving dihydroxyethylglycine while stirring is preferable, from the viewpoint of dispersion stability of the ceria particles when the components are combined. In addition, a process including the step of adjusting each of the ceria slurry and the aqueous dihydroxyethylglycine solution to a given pH prior to mixing, and thereafter mixing the components, or a process including the step of adjusting to a given pH after mixing, can be carried out.

[Preparation of Ceria Slurry]

The ceria slurry can be prepared by carrying out dispersion treatment. The dispersion treatment includes a method including the step of dispersing with a mixer such as a homomixer, a homogenizer, an ultrasonic disperser, or a wet ball-mill. In addition, it is preferable that a dispersant as mentioned above is used together upon the dispersion treatment from the viewpoint of dispersibility of the ceria particles. Here, it is preferable that the pH of the ceria slurry is adjusted to a range of from 3 to 10.

It is preferable that the ceria slurry obtained as described above is subsequently subjected to the removal of coarse grains. The method for removing the coarse grains includes, for example, centrifugation method or filtration method after the dispersion treatment.

In addition, it is preferable that the pH of the aqueous solution prepared by dissolving dihydroxyethylglycine is adjusted to a range of from 3 to 10.

[Optional Component]

In addition, the polishing composition of the present invention may be mixed with an anti-corrosive agent such as benzalkonium chloride, benzethonium chloride, 1,2-benzisothiazolin-3-one, (5-chloro-)2-methyl-4-isothiazolin-3-one, hydrogen peroxide, or a hypochlorite as an optional component (additive). In addition, the polishing composition of the present invention can be mixed with an oxidizing agent such as a peroxide or permanganic acid, chromic acid, nitric acid, peroxo acid, or a salt thereof. In addition, as a chelating agent other than the dihydroxyethylglycine, ethylenediaminetetraacetic acid (EDTA), cyclohexanediaminetetraacetic acid (CyDTA), nitrilotriacetic acid (NTA), hydroxyethylethylenediaminetriacetic acid (HEDTA), diethylenetriaminepentaacetic acid (DTPA), triethylenetetraminehexaacetic acid (TTHA), L-glutamatediacetic acid (GLDA), aminotri(methylenephosphonic acid), 1-hydroxyethylidene-1,1-diphosphonic acid, ethylenediaminetetra(methylenephosphonic acid), diethylenetriaminepenta(methylenephosphonic acid), β-alanine diacetic acid (β-ADA), α-alanine diacetic acid (α-ADA), aspartate diacetic acid (ASDA), ethylenediaminedisuccinic acid (EDDS), iminodiacetic acid (IDA), hydroxyethyliminodiacetic acid (HEIDA), 1,3-propanediaminetetraacetic acid (1,3-PDTA), malic acid, tartaric acid, gluconic acid, citric acid, aspartic acid, glutamic acid, glycine, 4-aminobutyric acid, arginine, phthalic acid or the like can be mixed in an amount within the range that would not impair the effects of the present invention. These optional components may be mixed with any of the ceria slurry or the aqueous dihydroxyethylglycine solution.

The above optional components can be added within the range that would not impair the effects of the present invention. The amount of the optional component is preferably from 0.001 to 1.0% by weight, and more preferably from 0.01 to 0.5% by weight of the polishing composition.

[pH of Polishing Composition]

The pH range of the polishing composition of the present invention obtained according to the above-mentioned process is preferably from 3 to 10, more preferably from 4 to 8, even more preferably from 4.5 to 7, even more preferably from 5 to 7, and even more preferably from 5.8 to 6.5, from the viewpoint of polishing rate.

The pH of the above-mentioned polishing composition can be adjusted with a pH adjusting agent. The pH adjusting agent includes basic substances such as ammonia, potassium hydroxide, a water-soluble organic amine and quaternary ammonium hydroxide, acidic substances such as an inorganic acid such as nitric acid, hydrochloric acid, sulfuric acid and phosphoric acid, and organic acids such as acetic acid, oxalic acid, succinic acid, glycolic acid, malic acid, citric acid and benzoic acid.

It is preferable that the polishing composition of the present invention is diluted upon use. The dilution fold is preferably 1.5-folds or more, more preferably 2-folds or more, even more preferably 3-folds or more, and even more preferably 4-folds or more, from the viewpoint of preparation and transportation costs. The dilution fold is preferably 20-folds or less, more preferably 15-folds or less, even more preferably 10-folds or less, and even more preferably 8-folds or less, from the viewpoint of polishing rate. Therefore, the dilution fold of the polishing composition of the present invention upon use is preferably from 1.5- to 20-folds, more preferably from 2- to 15-folds, even more preferably from 2- to 10-folds, and even more preferably from 2- to 8-folds.

As the dilution method, a method including the steps of adding a given amount of an aqueous medium to a polishing composition of the present invention, and mixing the components while stirring can be employed. More specifically, a method including the steps of placing a polishing composition of the present invention before polishing into a tank, adding a given amount of an aqueous medium thereto, and mixing the components while stirring; or a method including the step of adding an aqueous medium separately to the polishing composition of the present invention in the course of polishing can be employed.

[Semiconductor Substrate]

The polishing composition of the present invention is used for polishing a semiconductor substrate.

As to the semiconductor substrate in the present invention, the details are given later. The material for the semiconductor substrate includes, for example, metals or metalloids such as silicon, aluminum, nickel, tungsten, copper, tantalum and titanium, and alloys which contain these metals as a main component; glassy substances such as glass, glassy carbon and amorphous carbons; ceramic materials such as alumina, silicon dioxide, silicon nitride, tantalum nitride and titanium nitride; resins such as polyimide resins; and the like. Among them, those substrates having a film formed on its surface, the film containing a silicon atom and having a shape of a step height of dents and projections are preferable from the viewpoint of exhibiting efficient planarization. The film containing a silicon atom includes silicon oxides such as TEOS (tetraethoxysilane), quartz, and glass; silicon oxide, silicon nitride or polysilicon, each doped with an element such as phosphor or boron, such as BPSG (Boro-Phospho-Silicate Glass), PSG (Phospho-Silicate Glass); and the like. Especially, when polishing of a semiconductor substrate having a film to be polished containing silicon dioxide as a main component is carried out with the polishing composition of the present invention, efficient planarization can be realized.

In the case of silicon oxides to which an element such as phosphorus or boron is doped, such as BPSG or PSG, in order to exhibit planarization property, an even large amount of additives is required to be added as compared to a conventional silicon oxide film. However, the higher the concentration of the additive contained, the more easily the ceria particles are aggregated and precipitated due to the salting-out effect or the like; therefore, a polishing composition of the present invention having even more excellent dispersion stability can be more preferably used.

Among them, the polishing composition of the present invention is suitable for polishing a semiconductor substrate having a shape with a step height of dents and projections of from 50 to 2000 nm, and preferably from 100 to 1,500 nm, for the purpose of planarization of the semiconductor substrate. The step height can be obtained with a profile analyzer (for example, commercially available from KLA-Tencor Corporation under the trade name of HRP-100).

Especially when the semiconductor substrate having the step height is made of the same members, an excellent effect that the polishing of the projection portions can be carried out rapidly with the polishing composition of the present invention to achieve planarization is exhibited.

(2) Polishing Process

The polishing process of the present invention includes, for example, the step of feeding a liquid mixture prepared by diluting the above-mentioned polishing composition to a substrate to be polished at a rate of from 0.01 to 10 g/min per 1 cm² of the substrate.

[Feeding Rate of the Polishing Composition]

The feeding rate of the polishing composition (or a diluted liquid mixture thereof) is 0.01 g/min or more, and preferably 0.1 g/min or more per 1 cm² of a semiconductor substrate to be polished from the viewpoint of maintaining a high polishing rate and planarization in a short time, and the feeding rate is 10 g/min or less, and preferably 5 g/min or less per 1 cm² of a semiconductor substrate to be polished from the viewpoint of economic advantage and from the viewpoint of waste liquid treatment. Therefore, the feeding rate is from 0.01 to 10 g/min, preferably from 0.1 to 5 g/min.

[Polishing Load]

The polishing load is preferably 5 kPa or more, and more preferably 10 kPa or more from the viewpoint of the polishing rate, and preferably 100 kPa or less, more preferably 70 kPa or less, and even more preferably 50 kPa or less from the viewpoint of planarization and suppression of scratches of the surface to be polished. Therefore, the polishing load is preferably from 5 to 100 kPa, more preferably from 10 to 70 kPa, and even more preferably from 10 to 50 kPa.

The liquid mixture prepared by diluting a polishing composition is preferably, for example, a liquid mixture prepared by diluting the above-mentioned polishing composition in a preferred dilution fold mentioned above.

The polishing machine for a semiconductor substrate with the polishing composition (or a diluted liquid mixture thereof) of the present invention is not particularly limited, and a polishing machine equipped with jigs for supporting an object to be polished represented by a semiconductor substrate, and a polishing pad may be used for example. Specific examples of the polishing process using the polishing machine include a polishing process including the steps of polishing a surface of an object to be polished by pressing the above-mentioned jigs for supporting the object to be polished against polishing platens to which a polishing pad, such as one made of an organic polymer-based foamed article, a non-foamed article, or a nonwoven article, is attached, or alternatively by setting the substrate to be polished with polishing platens to which the polishing pad is pressed, feeding the polishing composition of the present invention to a surface of the substrate to be polished, and moving the polishing platens or the substrate to be polished, while applying a given pressure.

Here, the polishing conditions other than the feeding rate of the above-mentioned polishing composition or the polishing load are not particularly limited.

(3) Method for Manufacturing a Semiconductor Device

In general, a method for manufacturing a semiconductor device, such as memory IC, logic IC, or a system LSI, includes the steps of forming on a single crystallite substrate (wafer) typically made of silicon an insulation film made of silicon oxide or the like, and mounting metal electrodes thereon, thereby forming an element such as a transistor, a resistance, a capacitor, a diode, or a capacitance; forming a metal line between the above-mentioned elements; and forming chips from a substrate obtained through the above steps. In addition, the phrase “mounting metal electrodes” encompasses an embodiment of forming metal electrodes including the steps of forming a thin film such as an insulation film on a wafer, patterning the thin film by lithography, and further diffusing impurities, thereby forming a p-type region and/or an n-type region. The step of forming an insulation film and elements and/or the step of forming a metal line specifically includes the steps of subjecting to shallow trench isolation, subjecting an interlayer dielectric to planarization, forming an embedded metal line, forming an embedded capacitor, and the like. Here, the elements obtained in the step of forming the above-mentioned elements and/or the step of forming a metal line between elements, or the wafer in which the elements and the metal line are bonded to each other is referred to as a semiconductor substrate.

The method for manufacturing the semiconductor device of the present invention includes the step of polishing a semiconductor substrate with the polishing composition (or a diluted liquid mixture thereof) as defined above. Examples of the method include a method including the step of polishing a semiconductor substrate to be polished in accordance with the above-mentioned polishing process.

Here, the polishing conditions such as the polishing pad may be the same ones as in the above-mentioned polishing process.

Specifically, the method for manufacturing a semiconductor device includes a method including the steps of forming a thin film containing a silicon atom on an upper part of a semiconductor substrate having a shape of a step height of dents and projections, and polishing the thin film, wherein the polishing step includes feeding a polishing composition containing ceria particles, dihydroxyethylglycine, and a dispersant to the surface of a polishing pad, and subjecting the surface of the thin film having a shape of a step height of dents and projections to planarization by the CMP (chemical-mechanical polishing). The method as described above includes the steps of subjecting to shallow trench isolation, subjecting an interlayer dielectric to planarization, forming an embedded metal line, forming an embedded capacitor, and the like. Especially, the method is suitable for the step of subjecting to shallow trench isolation or the step of subjecting an interlayer dielectric to planarization, and preferably used for manufacturing a semiconductor device such as memory ICs, logic ICs, system or LSIs.

### EXAMPLES

The following examples further describe and demonstrate embodiments of the present invention. The examples are given solely for the purposes of illustration and are not to be construed as limitations of the present invention.

### Examples 1 to 7 and Comparative Examples 1 to 10

1. Evaluation of Dispersion Stability

Ion-exchanged water was added to dihydroxyethylglycine (commercially available from CHELEST CORPORATION, Chelest GA), aspartic acid (commercially available from Wako Pure Chemical Industries, Ltd.), ethylenediaminetetraacetic acid (commercially available from DOJINDO LABORATORIES, 4H), nitrilotriacetic acid (commercially available from CHELEST CORPORATION, Chelest NT), phthalic acid (commercially available from KISHIDA CHEMICAL Co., Ltd.), or polyacrylic acid (degree of neutralization of ammonia: 65% by mol, molecular weight: 6,000, solid content: 40% by weight), in a given amount as shown in Table 2, and the components were stirred to dissolve. To the solution in a stirring state was further added an aqueous dispersion of ceria (solid content of ceria: 40% by weight, average particle size of ceria particles: 125 nm, a crystallite size of ceria particles: 28 nm, the aqueous dispersion containing 0.1% by weight of ammonium polyacrylate having a molecular weight of 6,000 as a dispersant) in a given amount shown in Table 2. The pH of the resulting mixture was adjusted with an aqueous ammonia (ammonia: 28% by weight) (commercially available from TOMIYAMA PURE CHEMICAL INDUSTRIES, LTD.) to a pH of from 6.0 to 6.3, to give polishing compositions of Examples 1 to 7 and Comparative Examples 1 to 10. Here, the average particle size of the ceria particles is a median diameter on a volume basis as determined by laser diffraction scattering particle size analyzer (commercially available from Horiba, LTD., under the trade name of LA-920).

Using the polishing composition prepared as described above, the particle size determination of the ceria particles and the dispersibility test were carried out under the following conditions.

<Particle Size Determination of Ceria Particles in Polishing Composition>

As an index of aggregation level of the ceria particles in the polishing composition in a high-concentration state, the particle size of the ceria particles in a polishing composition after having allowed to stand for 1 day after the preparation was determined. Specifically, using a Microtrac particle size analyzer UPA-150 (commercially available from NIKKISO CO., LTD), the above-mentioned polishing composition was vibrated immediately before the determination, and sufficiently dispersed, and thereafter a determination was taken. Under the determination conditions of a specific gravity of ceria of 7.3, and determination time of 2 minutes, the determinations were taken consecutively three repeated runs. The particle size of the ceria particles was defined as a median diameter (D50) of a volume-average particle size.

<Dispersibility Test>

One-hundred milliliters of each polishing composition was stirred with a magnetic stirrer for 10 minutes, and thereafter the polishing composition was allowed to stand in a colorimetric tube equipped with a common stopper (tube diameter: 29 mm, volume: 100 ml) at room temperature (20° to 25° C.). The dispersion stability was judged from a separation state of the supernatant by precipitation of the ceria particles after passage of a given time period (after 1 day, after 3 days, and after 7 days). The judgment criteria are shown in Table 1, and the results are shown in Table 2.

TABLE 1
Evaluation Criteria

| | |
|---|---|
| ◯ | The separation height of supernatant being less than 10 mm; |
| Δ | The separation height of supernatant being 10 to 50 mm; and |
| X | Ceria being completely precipitated. |

TABLE 2

| | Components¹⁾ of Polishing Composition | | | | | |
|---|---|---|---|---|---|---|
| | | | | | Nitrilo- | |
| | | | Aspartic | | triacetic | Phthalic |
| | Ceria | DHEG⁴⁾ | Acid | Ethylenediamine- | Acid | Acid |
| | Concentration | Concentration | Concentration | tetraacetic Acid | Concentration | Concentration |
| Polishing | (% by | (% by | (% by | Concentration | (% by | (% by |
| Composition | weight)²⁾ | weight)²⁾ | weight)²⁾ | (% by weight)²⁾ | weight)²⁾ | weight)²⁾ |
| Ex. 1 | 7.5 | 6.5 | 0 | 0 | 0 | 0 |
| Ex. 2 | 3.0 | 12 | 0 | 0 | 0 | 0 |
| Ex. 3 | 10.0 | 8.7 | 0 | 0 | 0 | 0 |
| Ex. 4 | 12.0 | 10.4 | 0 | 0 | 0 | 0 |
| Ex. 5 | 14.0 | 12.1 | 0 | 0 | 0 | 0 |
| Ex. 6 | 20.0 | 17.3 | 0 | 0 | 0 | 0 |
| Ex. 7 | 3.0 | 2.6 | 0 | 0 | 0 | 0 |
| Comp. Ex. 1 | 3.0 | 0 | 1.4 | 0 | 0 | 0 |
| Comp. Ex. 2 | 7.5 | 0 | 0 | 0 | 0 | 0 |
| Comp. Ex. 3 | 7.5 | 0 | 0 | 0 | 0 | 0 |
| Comp. Ex. 4 | 3.0 | 0 | 0 | 0 | 0 | 0 |
| Comp. Ex. 5 | 7.5 | 6.5 | 0 | 0 | 0 | 0 |
| Comp. Ex. 6 | 25.0 | 21.7 | 0 | 0 | 0 | 0 |
| Comp. Ex. 7 | 3.0 | 0 | 0 | 0.9 | 0 | 0 |
| Comp. Ex. 8 | 3.0 | 0 | 0 | 0 | 1.2 | 0 |
| Comp. Ex. 9 | 3.0 | 0 | 0 | 0 | 0 | 1.0 |
| Comp. Ex. 10 | 3.0 | 0 | 0 | 0 | 0 | 0 |

| | Components¹⁾ of Polishing Composition | | | | | | | |
|---|---|---|---|---|---|---|---|---|
| | | Concentration | | | | | | |
| | | of DHEG⁴⁾ in | | | | | | |
| | Dispersant | Components | | | Particle Size | | | |
| | Concentration of | Excluding | | | of Ceria | | | |
| | Polyacrylic Acid | Aqueous | Weight | | Particles in | Dispersion Stability | | |
| | and Polyacrylic | Medium and | Ratio of | | Polishing | After | After | After |
| Polishing | Acid Salt | Ceria Particles | DHEG⁴⁾/ | | Composition | One | Three | Seven |
| Composition | (% by weight)^{2),3)} | (% by weight) | Ceria | pH | (μm) | Day | Days | Days |
| Ex. 1 | 0.0188 | 99.71 | 1/1.15 | 6.0 | 0.17 | ◯ | ◯ | ◯ |
| Ex. 2 | 0.0075 | 99.94 | 4/1 | 6.0 | 0.25 | ◯ | ◯ | ◯ |
| Ex. 3 | 0.0250 | 99.71 | 1/1.15 | 6.3 | 0.25 | ◯ | ◯ | ◯ |
| Ex. 4 | 0.0300 | 99.71 | 1/1.15 | 6.2 | 0.29 | ◯ | ◯ | ◯ |
| Ex. 5 | 0.0350 | 99.71 | 1/1.16 | 6.3 | 0.33 | ◯ | ◯ | ◯ |
| Ex. 6 | 0.0500 | 99.71 | 1/1.16 | 6.2 | 0.35 | ◯ | ◯ | ◯ |
| Ex. 7 | 0.0075 | 99.71 | 1/1.15 | 6.3 | 0.16 | ◯ | ◯ | ◯ |
| Comp. Ex. 1 | 0.0075 | 0 | 0 | 6.0 | 1.13 | X | X | X |
| Comp. Ex. 2 | 0.0188 | 0 | 0 | 6.0 | 0.15 | ◯ | ◯ | ◯ |
| Comp. Ex. 3 | 4.0188 | 0 | 0 | 6.0 | 1.17 | X | X | X |
| Comp. Ex. 4 | 4.0075 | 0 | 0 | 6.0 | 2.36 | X | X | X |
| Comp. Ex. 5 | 4.0188 | 62 | 1/1.15 | 6.0 | 1.11 | X | X | X |
| Comp. Ex. 6 | 0.0625 | 0 | 1/1.15 | 6.2 | Insoluble substances being present | | | |
| Comp. Ex. 7 | 0.0075 | 0 | 0 | 6.1 | 0.86 | ◯ | Δ | X |
| Comp. Ex. 8 | 0.0075 | 0 | 0 | 6.1 | 0.65 | X | X | X |
| Comp. Ex. 9 | 0.0075 | 0 | 0 | 6.2 | 0.63 | X | X | X |
| Comp. Ex. 10 | 4.0075 | 0 | 0 | 5.0 | 2.06 | X | X | X |

¹⁾Balance being ion-exchanged water and ammonia for Examples and Comparative Examples other than Comparative Example 1, and balance being ion-exchanged water in Comparative Example 1. Ammonia being used for pH adjustment, and its used amount being less than 0.001% by weight of the polishing composition.
²⁾Solid Content
³⁾Including polyacrylic acid salt contained in the ceria slurry. The polyacrylic acid and the polyacrylic acid salt do not serve as dispersants in Comparative Examples 3, 4, 5 and 10.
⁴⁾DHEG stands for dihydroxyethylglycine.

<Results of Dispersibility Test>

As shown by the results of Table 2, the polishing compositions of Examples 1 to 7 and Comparative Example 2 have smaller particle sizes of the ceria particles in the polishing composition, so that the ceria particles are not found to be aggregated and exhibit excellent dispersion stability. On the other hand, the polishing compositions of Comparative Examples 1, 3 to 5, and 7 to 10 have larger particle sizes of the ceria particles in the polishing composition, so that the ceria particles are found to be aggregated, and are disadvantage in dispersion stability. Also, the polishing composition of Comparative Example 6 contained insoluble substances.

2. Evaluation of Planarization Property (1)

Further, a diluted mixture prepared by diluting the above-mentioned polishing composition with ion-exchanged water was subjected to a polishing test under the following conditions.

<Polishing Test (1)>

1. Polishing Conditions
Polishing testing machine: single-sided polishing machine (product number: LP-541, commercially available from Lapmaster SFT Corp., platen diameter: 540 mm)
Polishing pad: product number: IC-1000/Sub400, commercially available from Nitta Haas Incorporated
Rotational speed of a platen: 60 r/min
Rotational speed of a head: 62 r/min (rotational direction being the same as that of the platen)
Polishing load: 40 kPa
Feeding rate of the polishing composition: 200 ml/min (0.6 g/cm²·min)
Substrate to be polished: a commercially available patterned wafer for evaluating CMP property Sematech 864 (a patterned wafer obtained by forming a silicon nitride film having a thickness of 170 nm on a silicon substrate with CVD (chemical vapor deposition) method, thereafter etching the substrate to form patterns in a depth of 500 nm, and forming a HDP-TEOS (high-density plasma tetraethoxysilane) silicon oxide film having a thickness of 600 nm on the patterned substrate; or a BPSG film patterned wafer (a patterned wafer obtained by patterning a silicone substrate (in the same shape as in Sematech 864) in a depth of 370 nm, and forming a BPSG film having a thickness of 1,000 nm on the silicone substrate)

The planarization property was evaluated by polishing a substrate to be polished for 2 minutes under the above-mentioned polishing conditions, and thereafter determining a remaining film thickness of the Sematech 864 or BPSG film patterned wafer. Specifically, the remaining film thicknesses in D20 pattern portion, D50 pattern portion, and D80 pattern portion (D20: Line & Space patterns having a width of projection portion of 20 μm and a width of dent portion of 80 μm; D50: Line & Space patterns having a width of projection portion of 50 μm and a width of dent portion of 50 μm; D80: Line & Space patterns having a width of projection portion of 80 μm and a width of dent portion of 20 μm) were determined. A step height (step height of projections and dents) was calculated from the remaining film thickness values. Here, the term “line & space” refers to a set of line pattern widths and spaces between the line patterns in portions where line patterns are repeatedly lined up in a metal line structure for IC or the like, and the term “line pitch” refers to a combined dimension of the line pattern widths and spaces between the line patterns. Sematech 864: Step Height=Remaining Film Thickness of Projection Portion (HDP Film+SiN Film)+Si Step Height−Remaining Film Thickness of Dent Portion
BPSG Film Patterned Wafer: Step Height=Remaining Film Thickness of Projection Portion+Si Step Height−Remaining Film Thickness of Dent Portion,
wherein Si step height refers to a depth of a dent portion in which the patterns are formed on a silicon wafer.

The Si step height of the wafer used in the present evaluation is 330 nm for Sematech 864 and 370 nm for the BPSG film patterned wafer. Here, the remaining film thickness was determined using a light interference-type film thickness gauge (LAMBDA ACE VM-1000, commercially available from DAINIPPON SCREEN MFG. CO., LTD.). The judgment criteria are shown in Table 3, and the results are shown in Table 4.

TABLE 3
Evaluation Criteria of Planarization Property

| | Sematech864 | | BPSG Film Patterned Wafer | |
|---|---|---|---|---|
| | Remaining Film Thickness | Remaining Film Thickness | Remaining Film Thickness of | |
| | of SiN Film | of Dent Portion | Dent Portion | |
| | Remaining film thickness | Film thickness difference | Film thickness difference | Step Height |
| | being 100 nm or more | between D20 pattern and | between D20 pattern and D80 | Within 50 nm in |
| | in Each Pattern | D80 pattern being within 150 nm | pattern being within 100 nm | Each Pattern |
| ◯ | Satisfied | Satisfied | Satisfied | Satisfied |
| Δ | Satisfied either one | | Satisfied | Not Satisfied |
| X | Not Satisfied | Not Satisfied | Not Satisfied | Satisfied/Not |
| | | | | Satisfied |

TABLE 4

| | | | | Determination | | | |
|---|---|---|---|---|---|---|---|
| | | | | Results of | | | |
| | Dilution | Substrate to Be | | Each Pattern | | | Planarization |
| | Fold | Polished | Determination Site | D20 | D50 | D80 | Property |
| Ex. 1 | 5 | Sematech864 | Remaining HDP FilmThickness | 0 | 0 | 0 | ◯ |
| | | | of Projection Portion | | | | |
| | | | Remaining SiN Film Thickness | 154 | 166 | 168 | |
| | | | Remaining Film Thickness of | 391 | 446 | 498 | |
| | | | Dent Portion | | | | |
| | | | Step Height | 93 | 50 | 0 | |
| Ex. 2 | 2 | BPSG Film | Remaining Film Thickness of | 438 | 511 | 538 | ◯ |
| | | Patterned | Projection Portion | | | | |
| | | Wafer | Remaining Film Thickness of | 805 | 853 | 884 | |
| | | | Dent Portion | | | | |
| | | | Step Height | 3 | 28 | 24 | |
| Comp. | 2 | Sematech864 | Remaining HDP Film Thickness | 0 | 0 | 15 | ◯ |
| Ex. 1 | | | of Projection Portion | | | | |
| | | | Remaining SiN Film Thickness | 154 | 166 | 167 | |
| | | | Remaining Film Thickness of | 427 | 468 | 502 | |
| | | | Dent Portion | | | | |
| | | | Step Height | 57 | 28 | 10 | |
| Comp. | 5 | Sematech864 | Remaining HDP Film Thickness | 0 | 0 | 0 | X |
| Ex. 2 | | | of Projection Portion | | | | |
| | | | Remaining SiN Film Thickness | 0 | 138 | 167 | |
| | | | Remaining Film Thickness of | 198 | 367 | 473 | |
| | | | Dent Portion | | | | |
| | | | Step Height | 132 | 101 | 24 | |
| | 5 | BPSG Film | Remaining Film Thickness of | 0 | 107 | 226 | X |
| | | Patterned | Projection Portion | | | | |
| | | Wafer*² | Remaining Film Thickness of | 370 | 477 | 596 | |
| | | | Dent Portion | | | | |
| | | | Step Height | 0 | 0 | 0 | |
| Comp. | 5 | Sematech864*¹ | Remaining HDP Film Thickness | 0 | 0 | 0 | ◯ |
| Ex. 3 | | | of Projection Portion | | | | |
| | | | Remaining SiN Film Thickness | 162 | 168 | 168 | |
| | | | Remaining Film Thickness of | 472 | 473 | 498 | |
| | | | Dent Portion | | | | |
| | | | Step Height | 20 | 25 | 0 | |
| Comp. | 2 | BPSG Film | Remaining Film Thickness of | 577 | 646 | 701 | Δ |
| Ex. 4 | | Patterned | Projection Portion | | | | |
| | | Wafer | Remaining Film Thickness of | 899 | 915 | 934 | |
| | | | Dent Portion | | | | |
| | | | Step Height | 48 | 101 | 137 | |

*¹Polishing time: 5 min
*²Polishing time: 1 min

<Evaluation Results of Planarization Property (1)>
Sematech 864: In a diluted mixture of Example 1, the HDP film on the projection portion formed on the silicon nitride film disappeared, and the polished amount of the silicon nitride film is slight. Further, the dent portion has a small pattern dependency, having a difference in HDP remaining film thickness between the D20 pattern and the D80 pattern within 150 nm, whereby excellent planarization property was obtained. In addition, even in the diluted mixtures of Comparative Examples 1 and 3, a surface having excellent planarization property could be obtained in the same manner as in the diluted mixture of Example 1. However, in the diluted mixture of Comparative Example 3, since its polishing rate is lowered, the HDP film remains on the projection portion in the polishing for 2 minutes, so that the desired planarization is not perfected, necessitating to extend the polishing time to 5 minutes. On the other hand, in the diluted mixture of Comparative Example 2, the HDP film on the projection portion disappeared, but the polishing further progressed even to the silicon nitride film beneath the HDP film, so that the silicon nitride film disappeared in the D20 patterned portion. Further, since the difference in the HDP remaining film thicknesses of the dent portion between the D20 pattern and the D80 pattern was 250 nm or more, the pattern dependency was large, so that excellent planarization property could not be obtained.
BPSG Film Patterned Wafer: In a diluted mixture of Example 2, the step height in each of the D20 pattern, the D50 pattern and the D80 pattern is within 30 nm, and further the dent portion has a small pattern dependency, having a difference in HDP remaining film thickness between the D20 pattern and the D80 pattern within 100 nm, whereby excellent planarization property was obtained. In the diluted mixture of Comparative Example 4, while the pattern dependency is excellent, having a difference in HDP remaining film thickness of the dent portion between the D20 pattern and the D80 pattern within 100 nm, the step height in the D80 pattern was 137 nm, so that the disadvantage in step height was not eliminated. On the other hand, in the diluted mixture of Comparative Example 2, since the BPSG film on the projection portion entirely disappeared in the polishing for 2 minutes, the polishing time was shortened to 1 minute, but in the D20 pattern, the BPSG film on the projection portion disappeared in the projection portion. Further, the dent portion has a large pattern dependency, having a difference in HDP remaining film thickness of the dent portion between the D20 pattern and the D80 pattern of 200 nm or more, whereby excellent planarization property was not obtained.

3. Evaluation of Planarization Property (2)

A diluted mixture prepared by diluting each of the polishing compositions of Examples 7 and 2 and Comparative Example 10 with ion-exchanged water in a dilution fold listed in Table 5 was subjected to a polishing test (2) under the following conditions.

<Polishing Test (2)>

1. Polishing Conditions
Polishing testing machine: single-sided polishing machine (product number: EPO222D, commercially available from Ebara Corporation)
Polishing pad: product number: IC-1000/Sub400, commercially available from Nitta Haas Incorporated
Rotational speed of a platen: 100 r/min
Rotational speed of a head: 107 r/min (rotational direction being the same as that of the platen)
Polishing load: 30 kPa
Feeding rate of the polishing composition: 200 ml/min (0.6 g/cm²·min)
Substrate to be polished: a commercially available patterned wafer for evaluating CMP property Sematech 864 (a patterned wafer obtained by forming a silicon nitride film having a thickness of 150 nm on a silicon substrate with CVD method, thereafter etching the substrate to form patterns in a depth of 500 nm, and forming a HDP-TEOS silicon oxide film having a thickness of 550 nm on the patterned substrate; or a BPSG film patterned wafer (a patterned wafer obtained by patterning a silicone substrate in a depth of 350 nm, and forming a BPSG film having a thickness of 1,000 nm on the silicone substrate

The polishing time was determined for each of the polishing compositions by measuring variation in coefficient of friction between the patterned wafer and the polishing pad by determining electric current of a driving motor of a platen, and detecting an end point of polishing.

The planarization property was evaluated by determining a remaining film thickness of the Sematech 864 or BPSG film patterned wafer. Specifically, the remaining film thicknesses in P25 pattern portion, P50 pattern portion, P100 pattern portion, P250 pattern portion, and P500 pattern portion (P25: Line & Space patterns having a width of projection portion of 12.5 μm and a width of dent portion of 12.5 μm; P50: Line & Space patterns having a width of projection portion of 25 μm and a width of dent portion of 25 μm; P100: Line & Space patterns having a width of projection portion of 50 μm and a width of dent portion of 50 μm; P250: Line & Space patterns having a width of projection portion of 125 μm and a width of dent portion of 125 μm; P500: Line & Space patterns having a width of projection portion of 250 μm and a width of dent portion of 250 μm) were determined. A step height (step height of projections and dents) was calculated from the remaining film thickness values.
Sematech 864: Step Height=Remaining Film Thickness of Projection Portion (HDP Film+SiN Film)+Si Step Height−Remaining Film Thickness of Dent Portion
BPSG Film Patterned Wafer: Step Height=Remaining Film Thickness of Projection Portion+Si Step Height−Remaining Film Thickness of Dent Portion,
wherein Si step height refers to a depth of a dent portion in which the patterns are formed on a silicon wafer.

The Si step height of the wafer used in the present evaluation is 350 nm for Sematech 864 and 350 nm for the BPSG film patterned wafer. Here, the remaining film thickness was determined using a light interference-type film thickness gauge (trade name: Aset F5x, commercially available from KLA Tencor Corporation). The results for determination of step height in each pattern are shown in Table 5.

TABLE 5

| | | Components of Diluted Polishing Composition | | | | | | | | |
|---|---|---|---|---|---|---|---|---|---|---|
| | | (% by weight)⁽¹⁾ | | | | | | | | |
| | | Ceria | DHEG | Polyacrylic Acid | | Determination Results in Step | | | | |
| | | Concentration | Concentration | Concentration | Substrate to Be | Height for Each Pattern (nm) | | | | |
| | Dilution Fold | (% by weight)⁽²⁾ | (% by weight)⁽²⁾ | (% by weight)⁽²⁾ | Polished | P25 | P50 | P100 | P250 | P500 |
| Ex. 7 | 2 | 1.5 | 1.3 | 0.0038 | Sematech864 | 17 | 43 | 36 | 39 | 39 |
| Ex. 2 | 2 | 1.5 | 6.0 | 0.0038 | BPSG Film | 36 | 65 | 73 | 68 | 79 |
| | | | | | Patterned Wafer | | | | | |
| Comp. | 2 | 1.5 | 0 | 2.0 | BPSG Film | 61 | 115 | 166 | 233 | 276 |
| Ex. 10 | | | | | Patterned Wafer | | | | | |

⁽¹⁾Balance being ion-exchanged water and aqueous ammonia.
⁽²⁾Calculated on solid basis
Notes:
The smaller the numerical figures in the table, the better the planarization property.

<Evaluation Results of Planarization Property (2)>

It can be seen that the diluted mixture of Example 7 and the diluted mixture of Example 2 have smaller values of step heights in any of the patterns, as compared to those of the diluted mixture of Comparative 10, whereby showing excellent planarization property.

4. Evaluation of Defects

A polishing test was conducted in the same manner as in the evaluation of planarization property (2) with each of the diluted mixtures of the polishing compositions of Examples 7 and 2 and Comparative Example 10 (listed in Table 5), except that a blanket wafer with thermal oxide film was used as a substrate to be polished. After polishing was carried out for 60 seconds, the substrate was cleaned for 60 minutes with a roller brush using an aqueous hydrogen peroxide (2% by weight). The number and size of the defects per entire side of a blanket wafer were obtained by laser-type defect testing apparatus (commercially available from KLA Tencor Corporation under the trade name of Surfscan SP1). Here, in the determination method, the number and size of the defects are calculated from the intensity and angle of the reflective light upon irradiating laser beam to the wafer surface.

Table 6 shows the results of the number of defects.

TABLE 6

| | | | | Number of Defects | | | 0.50 |
|---|---|---|---|---|---|---|---|
| | 0.10 μm | 0.12 μm | 0.14 μm | 0.17 μm | 0.20 μm | 0.30 μm | μm |
| Ex. 7 | 571 | 305 | 225 | 155 | 107 | 48 | 11 |
| Ex. 2 | 941 | 486 | 332 | 218 | 152 | 66 | 14 |
| Comp. | 12,501 | 7,442 | 4,462 | 2,213 | 1,185 | 251 | 29 |
| Ex. 10 | | | | | | | |

<Evaluation Results for Defects>

It can be seen that the number of defects on the level of 0.14 μm which is considered to be most realistic from the viewpoint of setting the recipe for the testing apparatus is markedly smaller in the diluted mixtures of Examples 7 and 2 as compared to those of the diluted mixture of Comparative Example 10, whereby showing excellent property.

It can be seen from the above that the polishing composition of the present invention can accomplish excellent dispersion stability in a high-concentration state and a high level of planarization without pattern dependency and defect reduction after polishing.

The polishing composition for a semiconductor substrate of the present invention is used, for example, for the steps of subjecting to shallow trench isolation, subjecting an interlayer dielectric to planarization, forming an embedded metal line, forming an embedded capacitor, and the like. Especially, the method is suitable for the step of shallow trench isolation or the step of subjecting an interlayer dielectric to planarization, and preferably used for manufacturing a semiconductor device such as memory ICs, logic ICs, or system LSIs.

The present invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

What is claimed is:

1. A polishing composition for a semiconductor substrate comprising dihydroxyethylglycine, ceria particles, a dispersant, and an aqueous medium, wherein the ceria particles are contained in an amount of from 2 to 22% by weight of the polishing composition, and the dispersant is contained in an amount of from 0.001 to 1.0% by weight of the polishing composition.

2. The polishing composition according to claim 1, wherein the dihydroxyethylglycine is contained in an amount of from 90 to 99.999% by weight of the components excluding the aqueous medium and the ceria particles.

3. The polishing composition according to claim 1, wherein the dihydroxyethylglycine is contained in an amount of from 0.4 to 40% by weight of the polishing composition.

4. The polishing composition according to claim 1, wherein a weight ratio of contents of the dihydroxyethylglycine to the ceria particles, i.e. dihydroxyethylglycine /ceria particles, is from 1/5 to 15/1.

5. The polishing composition according to claim 1, wherein the dispersant is at least one member selected from the group consisting of anionic surfactants, nonionic surfactants, acrylic acid copolymers, salts of acrylic acid copolymers, and ethylene oxide-propylene oxide block copolymers.

6. The polishing composition according to claim 1, wherein the semiconductor substrate has a film formed on its surface, the film containing at least a silicon atom and having a shape of a step height of projections and dents of from 50 to 2,000 nm.

7. A polishing process of a semiconductor substrate, comprising the step of feeding a liquid mixture prepared by diluting the polishing composition as defined in claim 1 to a substrate to be polished at a rate of from 0.01 to 10 g/min per 1 cm² of the substrate.

8. The polishing process according to claim 7, wherein polishing is carried out while pressing the substrate with a polishing pad at a polishing load of from 5 to 100 kPa.

9. A method for manufacturing a semiconductor device, comprising the step of polishing a substrate to be polished with the polishing process as defined in claim 7.

10. A method for manufacturing a semiconductor device, comprising the steps of forming an insulation film on a single crystal substrate and forming elements provided with a metal electrode thereon; forming metal line between said elements; and forming chips from the substrate obtained through the above steps, wherein the step of forming elements and/or the step of forming metal line comprises the step of polishing a substrate to be polished with the polishing process as defined in claim 7.

11. A polishing composition for a semiconductor substrate obtainable by a process comprising mixing dihydroxyethylglycine, ceria particles, a dispersant, and an aqueous medium, wherein an amount of the ceria particles is from 2 to 22% by weight, and an amount of the dispersant is from 0.001 to 1.0% by weight, of the polishing composition.

12. A polishing process of a semiconductor substrate, comprising the step of feeding a liquid mixture prepared by diluting the polishing composition as defined in claim 11 to a substrate to be polished at a rate of from 0.01 to 10 g/min per 1 cm² of the substrate.

13. The polishing process according to claim 12, wherein polishing is carried out while pressing the substrate with a polishing pad at a polishing load of from 5 to 100 kPa.

14. A method for manufacturing a semiconductor device, comprising the step of polishing a substrate to be polished with the polishing process as defined in claim 12.

15. A method for manufacturing a semiconductor device, comprising the steps of forming an insulation film on a single crystal substrate and forming elements provided with a metal electrode thereon; forming metal line between said elements; and forming chips from the substrate obtained through the above steps, wherein the step of forming elements and/or the step of forming metal line comprises the step of polishing a substrate to be polished with the polishing process as defined in claim 12.
